(19) United States
(12) Patent Application Publication
(10) Pub. No.: US 2026/0255564 A1
(43) Pub. Date: Aug. 27, 2026

(54) SHIELDING ELEMENT

(71) Applicant: ElringKlinger AG, Dettingen (DE)

(72) Inventors: Fabian ALBRECHT, Dettingen (DE); Gerd TRAXLER, Dettingen (DE); Eugen KÜBLER, Dettingen (DE); Thomas WOLF, Dettingen (DE); Armin EHNI, Dettingen (DE); Fabian VESENMAIER, Dettingen (DE)

(73) Assignee: ElringKlinger AG, Dettingen (DE)

(21) Appl. No.: 19/651,856

(22) Filed: Apr. 20, 2026

Related U.S. Application Data
(63) Continuation of application No. PCT/EP2024/079419, filed on Oct. 17, 2024.

(30) Foreign Application Priority Data
Oct. 19, 2023 (DE) 10 2023 128 735.4

(51) Int. Cl. H05K 9/00

(52) U.S. Cl. CPC H05K 9/0073

(57) ABSTRACT

A shielding element for electromagnetically shielding an electronic component, which shielding element has a low weight, is inexpensive to produce and is of simple construction, it is proposed that the shielding element comprises a main body having a coupling device by which the main body is couplable to a corresponding device, and comprises at least one electrically conductive layer which is provided at least in certain regions on and/or in the main body, wherein the main body and the at least one electrically conductive layer are interconnected, in particular are joined together by means of an injection molding operation, an injection compression molding operation and/or a pressing operation.

### RELATED INVENTION

This application is a continuation of international application No. PCT/EP2024/079419 filed on October 17, 2024, and claims the benefit of German application No. 10 2023 128 735.4 filed on October 19, 2023, which are incorporated herein by reference in their entirety and for all purposes.

### FIELD OF DISCLOSURE

The present invention relates to a shielding element for electromagnetically shielding an electronic component.

### BACKGROUND

For shielding electromagnetic radiation, use is normally made of housings composed of a metallic material. Such housings have a relatively high weight and high material and manufacturing costs.

### SUMMARY OF THE INVENTION

The present invention is based on the object of providing a shielding element which has a low weight, is inexpensive to produce and is of simple construction.

Said object is achieved according to the invention by means of a shielding element for electrically shielding an electronic component, comprising a main body, which has a coupling device by which the main body is couplable to a corresponding device, and comprising at least one electrically conductive layer, which is provided at least in certain regions on and/or in the main body, wherein the main body and the at least one electrically conductive layer are interconnected, in particular are joined together by means of an injection molding operation, an injection compression molding operation and/or a pressing operation.

Such a shielding element may be designed in particular as a lid element, housing element, cover element and/or the like.

For example, the shielding element may be designed as a lid element which is couplable by means of the coupling device to the corresponding device, which is preferably designed as a housing.

The coupling device may preferably involve a connecting portion, for example a flange-like connecting portion, by means of which the shielding element is releasably couplable to the corresponding device.

In particular, the shielding element and the corresponding device may jointly form an interior space which is shielded with respect to electromagnetic radiation and in which the electronic component, for example an electronic module, a battery device and/or the like, is received.

The at least one electrically conductive layer is provided for forming a shield with respect to electrical and/or magnetic fields.

For this purpose, the electrically conductive layer extends in and/or on the main body preferably areally, preferably over the entire area thereof.

The main body may be of any geometrical design; preferably, the main body may be formed as a substantially areally extending component.

The main body may advantageously have an areally extending wall portion on which an edge portion is provided which at least partially surrounds the wall portion. The wall portion is preferably delimited around the entire periphery by the edge portion. The edge portion may be of flange-like form.

The coupling device may preferably be provided on said edge portion.

The main body is formed in particular as an injection-molded part.

The main body is preferably formed from a plastics material, for example a thermoplastic, or a fiber-reinforced plastics material.

The main body may be formed and/or produced for example by way of a conventional injection molding operation or by way of a foam injection molding operation or by way of an injection compression molding operation or by way of a pressing operation.

The electrically conductive layer is advantageously overmolded with the main body, and/or the main body is molded and/or pressed and/or compression-molded onto the electrically conductive layer.

For this purpose, during the injection molding operation, the injection compression molding operation and/or the pressing operation, the electrically conductive layer is inserted into an injection mold, and the plastics material or the fiber-reinforced plastics material is subsequently supplied, in particular injected into the injection mold, in order to thus form the main body with the electrically conductive layer arranged thereon and/or therein.

Additionally, one or more reinforcement elements, for example in the form of an insert or the like, may be provided in and/or on the main body.

In the case of a pressing process, it is for example possible for a flow molding compound, in particular a DLFT/GMT flow molding compound, to be provided or used.

A refinement of the shielding element may provide for the coupling device to have at least one electrically conductive contact portion by means of which the coupling device can be electrically contacted with the corresponding device.

Since, during the coupling of the shielding element to the corresponding device, an electrical connection can be established between these by means of the electrically conductive contact portion, comprehensive shielding with respect to electromagnetic radiation can be achieved.

The electrically conductive contact portion of the coupling device may be provided for example by an electrically conductive surface which is provided on the main body in a direction facing away from the main body, that is to say in the direction of the corresponding device that is to be coupled.

An advantageous refinement of the shielding element may provide for the at least one electrically conductive contact portion to be formed at least in part by the electrically conductive layer and/or to be contacted with the at least one electrically conductive layer.

Preferably, the electrically conductive layer may form, in the region of the coupling device, an electrically conductive surface by means of which the electrically conductive contact portion is formed.

In particular, provision may be made for the electrically conductive surface that is formed by the electrically conductive layer to be provided on the main body in a direction facing away from the main body, that is to say in the direction of the corresponding device to be coupled.

A refinement of the shielding element may furthermore provide for the coupling device to have at least one passage provided in the main body, wherein an electrically conductive element is provided in the passage and forms the contact portion and/or is contacted with the contact portion.

Preferably, the at least one passage is provided for the insertion of a fastening means, in particular a screw, for the purposes of attaching, in particular screwing, the shielding element to the corresponding device.

Preferably, the fastening means inserted into the at least one passage is electrically contacted with the electrically conductive element provided in the passage.

Preferably, multiple such passages are formed on the main body, for example along the edge region or flange portion which delimits the main body.

The electrically conductive element may involve an electrically conductive material which is provided, for example as an electrically conductive coating, on an inner wall portion of the passage.

In particular, an electrically conductive sleeve, for example composed of a metallic material, is inserted into the at least one passage.

The electrically conductive sleeve preferably extends all the way through the passage in the main body.

The electrically conductive sleeve may preferably form a circular passage cross section.

The electrically conductive sleeve preferably forms an inner wall of the at least one passage.

An internal thread may be provided on an inner wall portion of the electrically conductive sleeve.

The electrically conductive sleeve may advantageously be arranged in the passage of the main body, by virtue of said sleeve being overmolded with the plastics material or the fiber-reinforced plastics material or being introduced, in particular molded or pressed, into the passage of the main body.

In a refinement of the shielding element, the at least one electrically conductive contact portion may be formed at least in part by an end face or a flange portion of the electrically conductive element, in particular of the electrically conductive sleeve.

Preferably, during the coupling to the corresponding device, the electrically conductive element, in particular the electrically conductive sleeve, is electrically contactable with the corresponding device by way of the end face or the flange portion.

The end face or the flange portion of the electrically conductive element, in particular of the electrically conductive sleeve, is preferably recessed flush into the main body, or protrudes relative thereto.

In a further advantageous refinement of the shielding element, provision may be made whereby, on the main body, there is provided at least one electrically conductive projection by means of which, during the coupling to the corresponding device, the electrically conductive layer is electrically contactable with said device.

It may be advantageous if the electrically conductive projection has an elevated projection zone.

The projection zone may advantageously be electrically conductive in particular at a most highly elevated contact zone of the projection. For example, the contact zone may form a summit zone of the projection.

The projection zone may in particular be elevated in relation to a base portion of the shielding element. The edge portion may be the base portion or may have the base portion. It may be advantageous if the electrically conductive projection has a body zone and the projection zone, wherein the projection is more highly elevated in the projection zone than in the body zone.

It may be advantageous if the projection has a greater extent in at least one projection extent direction in the body zone than in the more highly elevated projection zone.

The at least one projection extent direction may advantageously extend transversely to a projection elevation direction in which the projection is elevated.

It may be advantageous if the projection tapers from the body zone via the projection zone toward the contact zone.

The at least one electrically conductive projection is preferably formed by the main body. For example, the at least one electrically conductive projection may be formed by way of the injection molding operation, the injection compression molding operation and/or the pressing operation for the main body.

The at least one electrically conductive projection may advantageously extend along at least part of, preferably around the entire periphery of, the edge portion or flange portion of the main body on which the coupling device is provided and which at least partially surrounds the wall portion of the main body.

In particular, the at least one electrically conductive projection is arranged between the coupling device and the wall portion of the main body.

Preferably, the at least one electrically conductive projection is at least partially covered by the electrically conductive layer. Thus, during the coupling of the shielding element to the corresponding device, electrically conductive contact can be established between the electrically conductive layer and the corresponding device.

For example, the projection may have a flank.

The flank may advantageously extend obliquely and/or be inclined relative to the projection elevation direction.

For example, a gradient of the flank may, at at least one point, be neither horizontal nor vertical.

The terms horizontal and vertical may advantageously relate to the projection elevation direction, wherein vertical may mean parallel to the projection elevation direction and horizontal may mean orthogonal to the projection elevation direction.

A gradient of the flank may advantageously increase from the contact zone toward the body zone, and/or decrease at the transition from the body zone into the base portion.

The electrically conductive layer may advantageously entirely or partially cover or form the flank.

The electrically conductive layer may advantageously extend on the flank over the body zone and the projection zone up to the contact zone.

For example, the flank may be a first flank, and the projection may have a second flank.

It may be advantageous if, in the at least one projection extent direction, the projection has the greater extent in the body zone than in the more highly elevated projection zone, wherein the extent in the projection extent direction in the body zone and in the projection zone is measurable in each case from the first flank to the second flank.

The electrically conductive layer may advantageously entirely or partially cover or form the first flank and entirely or partially cover or form the second flank.

The electrically conductive layer may advantageously extend on the first flank over the body zone and the projection zone up to the contact zone, and extend on the second flank from the contact zone down through the projection zone into the body zone or through the body zone.

Such projections have proven to be particularly advantageous specifically with regard to simple and/or inexpensive production of shielding elements. For example, for this purpose, an injection mold may be used which has a depression corresponding to the projection. Before the actual injection molding operation, a material suitable for forming the electrically conductive layer, for example a metal foil, may be arranged in the injection mold. The electrically conductive projection can then be produced directly during the injection molding operation by virtue of the material suitable for forming the electrically conductive layer being deformed into the depression, thus forming the electrically conductive projection, by injected plastics material from which, for example, the main body can be formed.

In a refinement of the shielding element, the electrically conductive layer may be formed at least in part from a metallic material.

In particular, the electrically conductive layer may be formed entirely or in part from a metallic material and/or a metallic alloy.

Preferably, the electrically conductive layer is formed at least in part from aluminum, copper, iron, nickel, silver and/or the like.

An alternative refinement of the shielding element may provide for the electrically conductive layer to be formed at least in part from an electrically conductive organic material.

In particular, the electrically conductive organic material may involve carbon, for example carbon fibers.

The electrically conductive organic material may likewise involve graphite and/or the like.

In a refinement of the shielding element, provision may furthermore be made for the electrically conductive layer to be formed at least in part from a combination of an electrically conductive material and an electrically non-conductive material.

For example, the electrically conductive layer may be formed from a non-conductive organic material which is provided with an electrically conductive material, in particular a metallic material, a metallic alloy or an electrically conductive organic material, for example carbon, graphite or the like.

In an advantageous refinement of the shielding element, the electrically conductive layer may be formed at least in part from a woven fabric, a laid scrim, a weft-knitted fabric, a warp-knitted fabric, a nonwoven and/or the like, which is provided with an electrically conductive material.

The electrically conductive layer may preferably be formed at least in part from a knitted fabric of any configuration.

The woven fabric, laid scrim, weft-knitted fabric, warp-knitted fabric, nonwoven and/or the like may in particular be formed at least in part from a metallic material, electrically conductive organic material and/or the like.

For example, the woven fabric, laid scrim, weft-knitted fabric, warp-knitted fabric, nonwoven and/or the like may be formed from a fibrous material consisting of a plastics material, a metallic material, carbon, graphite and/or the like.

The woven fabric, laid scrim, weft-knitted fabric, warp-knitted fabric, nonwoven and/or the like may advantageously be formed from an electrically non-conductive material which is provided, for example coated, with an electrically conductive material.

A particularly advantageous refinement of the shielding element may provide for the electrically conductive layer to be formed at least in part as a foil, a metal sheet, a perforated metal sheet, an expanded metal, an expanded metal mesh or the like.

Such a foil, such a metal sheet, such a perforated metal sheet, such an expanded metal, such an expanded metal mesh or the like may be provided on a surface of the main body, preferably on a surface, which forms the inner side, of the main body, by way of the injection molding operation, the injection compression molding operation and/or the pressing operation.

Likewise, such a foil, such a metal sheet, such a perforated metal sheet, such an expanded metal, such an expanded metal mesh or the like may be introduced into the main body, in particular overmolded with the injection molding material, by way of the injection molding operation, the injection compression molding operation and/or the pressing operation.

In a refinement of the shielding element, an adhesion promoter may be provided at least in certain regions between the main body and the electrically conductive layer.

Such an adhesion promoter is also referred to as a primer. A chemical and/or physical connection between the main body and the electrically conductive layer can be formed by means of the adhesion promoter.

In particular, by means of the adhesion promoter, improved adhesion is achieved between an electrically conductive layer formed as a foil and the main body formed from a plastics material.

In the case of the shielding element, provision may advantageously be made for the electrically conductive layer to have, at least in certain regions, a layer thickness of at least approximately 0.003 mm, in particular at least approximately 0.005 mm, and/or at most approximately 1 mm, in particular at most approximately 0.8 mm.

For example, it may be advantageous if the electrically conductive layer is formed at least in part as a foil, and the foil is a metal foil. It may be particularly advantageous if the metal foil is formed at least in part from aluminum, copper, iron, nickel, silver and/or the like.

It may be very particularly advantageous if the metal foil is formed at least in part from aluminum. The metal foil formed at least in part from aluminum may contain aluminum or an aluminum alloy, in particular may consist of aluminum or an aluminum alloy.

A thickness of the metal foil may advantageously be 0.03 to 0.6 mm, in particular 0.05 to 0.5 mm, advantageously 0.06 to 0.4 mm, for example 0.07 to 0.3 mm.

However, the advantages that have been described in conjunction with an injection mold which has the depression corresponding to the projection can for example be implemented not only with such metal foils.

A total thickness of the main body and of the electrically conductive layer may, at least in certain regions, for example in the region of the wall portion of the main body, lie in the range from approximately 2 mm to approximately 8 mm.

In a further advantageous refinement of the shielding element, at least in certain regions, there may be a ratio of approximately 1/1 to approximately 1/10000 between a layer thickness of the electrically conductive layer and a thickness of the main body.

In particular, such a ratio between the layer thickness of the electrically conductive layer and the thickness of the main body is provided in the region of the wall portion formed by the main body.

A preferred refinement of the shielding element may furthermore provide for the main body to be formed as a multi-ply injection-molded part, wherein the at least one electrically conductive layer is provided at least between two adjacent plies.

The multiple plies of the main body are preferably formed from the same material.

Alternatively, provision may also be made for the multiple plies of the main body to be formed from different materials, for example from different plastics materials.

It may be advantageous if the shielding element has a seal element.

It may be advantageous if the shielding element has the seal element on the main body.

It may be advantageous if the seal element is an external seal element.

The external seal element can advantageously seal off the passage. For example, the external seal element may seal off the passage, with the fastening means insertable or inserted therein, toward an outer side of the main body.

In particular, the external seal element may be arranged at the passage such that, when a fastening means which can be inserted into the passage, and which may for example be a screw, is inserted, said seal element can come to lie against a head of the fastening means, for example against the screw head of the screw.

In particular, the external seal element is designed as an annular seal, for example as an O-ring, which is arranged so as to surround the passage.

The external seal element may be received in a groove formed on the main body.

It may be advantageous if the seal element is an inner seal element, wherein the shielding element may have the inner seal element for example on the inner side of the main body.

It may be advantageous if the inner seal element is arranged at an external side on the edge portion of the main body, in particular in order to be able to form a seal toward an outer side of the main body when the shielding element is coupled to the corresponding device.

The inner seal element may for example

- be formed as a seal composed of an elastomer material, for example of a plastics material, of rubber or the like,

or

- be formed as a liquid seal.

It may be advantageous if the inner seal element is arranged at an edge of the electrically conductive layer, for example in order to form a seal with respect to the outer side. It is advantageously possible that one part of the inner seal element covers the edge of the electrically conductive layer, and another part of the inner seal element is arranged offset with respect to the edge.

It may be advantageous if the inner seal element is arranged at a transition from the electrically conductive element to the electrically conductive layer, for example in order to form a seal with respect to the outer side.

It may be advantageous if the inner seal element is arranged between the electrically conductive element and the electrically conductive layer, for example in order to form a seal with respect to the outer side.

The inner seal element may advantageously be arranged in a groove formed in the main body. The groove may preferably be provided or extend adjacent to the electrically conductive element.

The inner seal element may advantageously be designed such that at least one portion of the inner seal element extends along at least one portion of the projection.

The projection may advantageously be at least one electrically conductive projection extending along at least part of, preferably around the entire periphery of, the edge portion or flange portion of the main body.

In particular, the inner seal element may extend along the projection around the entire periphery, for example as an annular seal, along the edge portion or flange portion of the main body.

The inner seal element may be formed in particular from an elastomer material, for example from a plastics material, from rubber or the like.

It may be advantageous if the seal element, for example the inner seal element, is a liquid seal.

The liquid seal may for example be arranged at the inner side on a surface of the main body or on a surface of the electrically conductive layer.

In particular, the inner seal element, for example the liquid seal, may be arranged between the projection and the coupling device.

It may be advantageous if the seal element, for example the inner seal element or the liquid seal, is electrically conductive. For this purpose, the seal element may for example include an electrically conductive additive, for example a metal powder or a graphite powder, or may have an electrically conductive coating. It may be advantageous if the electrically conductive seal element is arranged such that an electrically conductive connection from the electrically conductive layer to the corresponding device can be established by means of the electrically conductive seal element.

The main body may advantageously be of single-ply form.

The main body may advantageously be of multi-ply form. It may be advantageous if the multi-ply main body comprises an outer ply and an inner ply. It may be advantageous if the electrically conductive layer extends at least in certain regions in the main body between the outer ply and the inner ply.

It may be advantageous if at least one portion of the inner seal element is arranged in a groove formed in the inner ply of the main body, or is arranged in a groove delimited by the inner ply and the electrically conductive element.

It may be advantageous if at least one portion of the groove extends at the inside in relation to the electrically conductive contact portion and/or extends as far as the electrically conductive contact portion.

The inner seal element may advantageously extend along at least part of the edge portion of the main body, in particular along the edge portion of the main body around the entire periphery, for example as an annular seal.

The inner seal element may advantageously be received in a recess delimited by the outer ply and/or the inner ply and/or the electrically conductive layer.

The inner seal element may advantageously be arranged adjacent to the flange portion of the electrically conductive element.

A recess formed by the outer ply and the inner ply may advantageously be designed in particular to receive the flange portion of the electrically conductive element and the inner seal element.

The inner seal element may advantageously be formed as an annular seal, for example as an O-ring, which surrounds the flange portion of the electrically conductive element.

For example, provision may also be made for at least one ply of the main body to be formed by way of a conventional injection molding operation, injection compression molding operation and/or pressing operation, and for at least one further ply of the main body to be formed by way of a foam injection molding operation, and for the at least one electrically conductive layer to be provided in between.

Further preferred features and/or advantages of the invention are discussed in the following description and shown in the illustration of exemplary embodiments in the drawing.

### BRIEF DESCRIPTION OF THE DRAWINGS

FIG. 1 shows a schematic sectional view of a shielding element according to a first embodiment according to the disclosure;

FIG. 2 shows a schematic sectional view of the shielding element according to a second embodiment according to the disclosure;

FIG. 3 shows a schematic sectional view of the shielding element according to a third embodiment according to the disclosure;

FIG. 4 shows a schematic sectional view of the shielding element according to a fourth embodiment according to the disclosure;

FIG. 5 shows a schematic sectional view of the shielding element according to a fifth embodiment according to the disclosure; and

FIG. 6 is an enlarged illustration of the projection shown in FIG. 3.

Identical or functionally equivalent elements are denoted by the same reference signs throughout the figures.

### DETAILED DESCRIPTION OF THE DRAWINGS

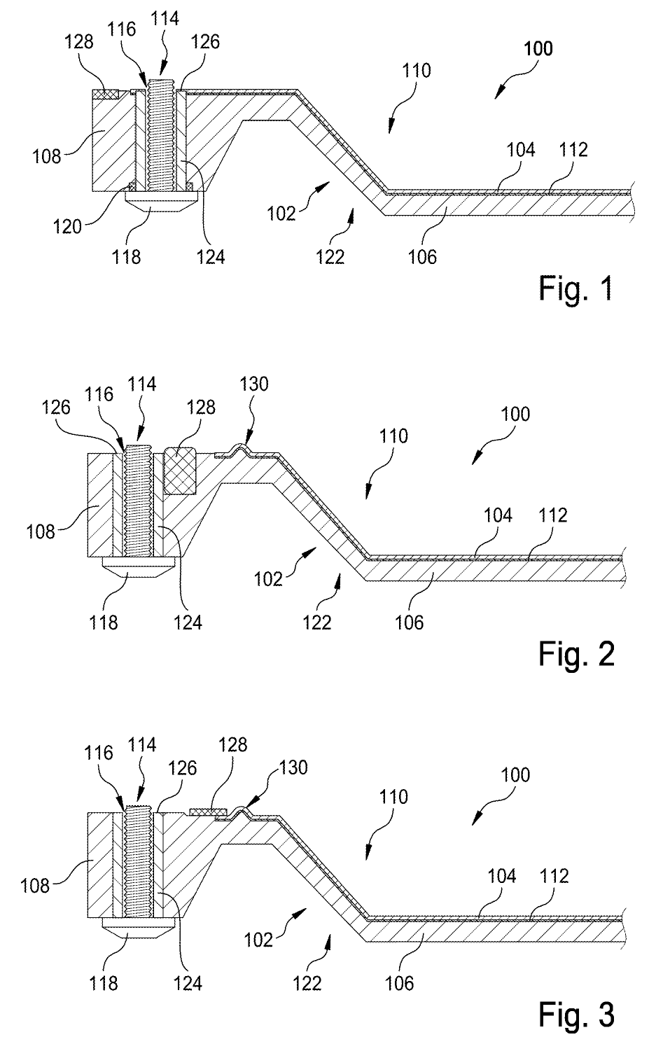

FIG. 1 shows a schematic sectional view of a shielding element, denoted as a whole by 100, for electromagnetically shielding an electronic component (not illustrated in any more detail), according to a first embodiment according to the disclosure.

The shielding element 100 is in particular a lid element, a housing element or a cover element which, in order to electromagnetically shield the electronic component, is couplable to a corresponding device (not illustrated in any more detail), in particular a corresponding housing element, for receiving the electronic component.

The corresponding device, in particular the corresponding housing element, together with the shielding element 100 arranged thereon may preferably form an interior space in which the electronic component, for example a battery unit, an electronic module or the like, is received in electromagnetically shielded fashion.

The shielding element 100 comprises a main body 102 and an electrically conductive layer 104 provided on the main body 102.

The main body 102 is formed as an injection molded part from a plastics material, for example a thermoplastic, or a fiber-reinforced plastics material.

The main body 102 may be formed both by way of a conventional injection molding operation and by way of a foam injection molding operation, an injection compression molding operation and/or a pressing operation.

The main body 102 may have any desired geometrical design; for example, the main body 102 may have a substantially rectangular, circular, oval or similar basic shape as seen in a plan view.

In particular, the main body 102 has a substantially planar basic shape.

The main body 102 is formed substantially by a wall portion 106 and by an edge portion 108 adjoining the wall portion 106.

The edge portion 108 is preferably provided in the form of a flange on the wall portion 106.

In particular, the wall portion 106 and the edge portion 108 are formed integrally with one another.

The wall portion 106 may have a substantially rectangular, circular, oval or similar basic shape as seen in a plan view and is preferably surrounded or delimited around the entire periphery by the edge portion 108.

The wall portion 106 may for example have a wall thickness of approximately 2 mm to approximately 8 mm.

The electrically conductive layer 104 is applied to a surface of the main body 102.

In particular, the electrically conductive layer 104 is applied to the surface of the main body 102 over the entire area thereof.

The electrically conductive layer 104 has a layer thickness of for example at least approximately 0.005 mm to at most approximately 1 mm.

According to FIG. 1, the electrically conductive layer 104 is arranged on an inner side 110 of the shielding element 100. In the illustration of FIG. 1, the inner side 110 of the shielding element 100 forms a top side, or a side facing an interior space, of the shielding element 100.

In other words, when the shielding element 100 is coupled to the corresponding device, the electrically conductive layer 104 provided on the inner side 110 of the shielding element 100 faces the interior space in which the electronic component that is to be electromagnetically shielded is arranged.

The electrically conductive layer 104 and the main body 102 are joined together in particular by way of the injection molding operation, the injection compression molding operation and/or the pressing operation.

In order to permanently interconnect the main body 102 and the electrically conductive layer 104, an adhesion promoter 112 is preferably provided between these.

Such an adhesion promoter 112 strengthens the chemical and/or physical connection between the main body 102 and the electrically conductive layer 104, and is also referred to as a primer.

The electrically conductive layer 104 may take on a variety of forms, as will be described below.

The electrically conductive layer 104 may preferably be formed from a metallic material, in particular from a metallic material or a metallic alloy.

For example, the electrically conductive layer 104 may be formed from aluminum, copper, iron, nickel, silver or the like.

Alternatively, the electrically conductive layer 104 may consist of an electrically conductive organic material, in particular of carbon, preferably carbon fibers, graphite or the like.

Provision may also be made for the electrically conductive layer 104 to be formed from a combination of at least one of the aforementioned electrically conductive materials and an electrically non-conductive material.

For example, an electrically non-conductive material may be provided or coated with an electrically conductive material, in particular a metallic material or an electrically conductive organic material.

For example, the electrically conductive layer 104 may be formed from a knitted fabric of any type. For example, the electrically conductive layer 104 may be formed from a woven fabric, a laid scrim, a weft-knitted fabric, a warp-knitted fabric, a nonwoven or the like, which is provided or coated with a corresponding electrically conductive material.

The woven fabric, laid scrim, weft-knitted fabric, warp-knitted fabric, nonwoven or the like may be formed either from an electrically conductive material, in particular a metallic material, electrically conductive organic material or the like, or from an electrically non-conductive material, for example from a fiber material, preferably from a plastics material, which is provided or coated with an electrically conductive material.

The electrically conductive layer 104 may advantageously also be formed as a foil, a metal sheet, a perforated metal sheet, an expanded metal, an expanded metal mesh or the like composed of one of the aforementioned electrically conductive materials.

The foil, the metal sheet, the perforated metal sheet, the expanded metal, the expanded metal mesh or the like is formed in particular from a metallic material, for example from aluminum, copper, iron, nickel, silver or the like, or from an electrically conductive organic material, in particular from carbon, preferably carbon fibers, graphite or the like.

Provided on the edge portion 108 is a coupling device 114 by means of which the shielding element 100 is attachable, in particular releasably attachable, to a correspondingly designed coupling device of the corresponding device.

For example, the coupling device 114 is formed as a flange-like connecting portion.

In particular, the coupling device 114 has a plurality of passages 116 which each extend through the edge portion 108 of the main body 102.

In particular, the plurality of passages 116 are spaced apart from one another along the edge portion 108.

The passages 116 are designed such that a fastening means 118, in particular a screw, can be inserted into each of said passages in order to fasten, in particular screw, the shielding element 100 to the corresponding device.

An external seal element 120 may be provided on the main body 102, said external seal element sealing off the passage 116, with the fastening means 118 inserted therein, toward an outer side 122 of the main body 102.

In particular, the external seal element 120 is arranged between a screw head of the fastening means 118 designed as a screw.

In particular, the external seal element 120 is designed as an annular seal, for example as an O-ring, which is arranged so as to surround the passage 116.

The external seal element 120 may be received in a groove formed on the main body 102.

An electrically conductive, sleeve-shaped element 124 is provided in each of the plurality of passages 116. Said sleeve-shaped element 124 is inserted into the passage 116, for example is overmolded with the main body or is introduced, molded or pressed into the passage 116 of the main body 102.

The sleeve-shaped element 124 is preferably formed from a metallic material, from carbon, from graphite or the like.

The sleeve-shaped element 124 preferably extends all the way through the passage 116.

The sleeve-shaped element 124 has a circular passage cross section, such that the fastening means 118, in particular the screw, can be inserted therein.

An internal thread for the fastening means 118 to be screwed into may be formed in the sleeve-shaped element 124.

Electrical contact is preferably established between the sleeve-shaped element 124 and the fastening means 118.

Toward the inner side 110 of the shielding element 100, the sleeve-shaped element 124 forms an electrically conductive contact portion 126.

In particular, the electrically conductive contact portion 126 is formed by an end face of the sleeve-shaped element 124.

Here, the end face of the sleeve-shaped element 124 may either be recessed flush into the main body 102 on the inner side 110, or may protrude relative to a surface on the inner side 110.

The electrically conductive contact portion 126 is designed such that, when the shielding element 100 is coupled to the corresponding device, the electrically conductive contact portion establishes electrical contact with said device.

The electrically conductive layer 104 may be formed on the inner side 110 of the main body 102 such that the electrically conductive contact portion 126 is formed both by the end face of the sleeve-shaped element 124 and by the electrically conductive layer 104.

For example, the electrically conductive layer 104 may be formed on the inner side 110 of the main body 100 so as to surround the passage 116 or the sleeve-shaped element 124, that is to say the end face of the sleeve-shaped element 124.

The electrically conductive layer 104 may likewise be formed so as to at least partially cover the end face of the sleeve-shaped element 124 on the inner side 110 of the main body 100.

Provision may thus preferably be made for the electrically conductive contact portion 126 to be formed only by the electrically conductive layer 104 or to be formed by the electrically conductive layer 104 and the end face of the sleeve-shaped element 124 jointly.

An inner seal element 128 may be provided on the inner side 110 of the main body 102.

Said inner seal element 128 is arranged at an external side on the edge portion 108 of the main body 102 in order to form a seal toward the outer side 122 when the shielding element 100 has been coupled to the corresponding device.

The inner seal element 128 may be formed either as a seal composed of an elastomer material, for example of a plastics material, of rubber or the like, or as a liquid seal.

FIG. 2 illustrates a schematic sectional view of the shielding element 100 according to a second embodiment according to the disclosure.

Only differences between this second embodiment of the shielding element 100 and the above-described first embodiment of the shielding element 100 will be discussed below. Equivalent designs will not be discussed again, and may in particular correspond to the first embodiment of the shielding element 100.

In this second embodiment of the shielding element 100, an electrically conductive projection 130 is formed on the main body 102 on the inner side 110 of the main body 102.

Said electrically conductive projection 130 is provided in order to establish electrical contact between the electrically conductive layer 104 and the corresponding device during the coupling of the shielding element 100.

The projection 130 is formed by the main body 102 and is formed in particular by way of the injection molding operation, the injection compression molding operation and/or the pressing operation. Said projection may however also be attached to the main body 102 after the injection molding operation, the injection compression molding operation and/or the pressing operation.

The projection 130 is preferably provided on an opposite side of the coupling device 114 in relation to the external edge portion 108.

In other words, the projection 130 is arranged between the coupling device 114 and the wall portion 106 of the main body 102.

The projection 130 is preferably formed as a bead which extends along at least part of the edge portion 108 of the main body 102.

In particular, the projection 130 extends along the edge portion 108 of the main body 102 around the entire periphery.

To establish the electrical conductivity of the projection 130, said projection is covered by the electrically conductive layer 104 provided on the inner side 110.

Since the projection 130 protrudes relative to the main body 102 on the inner side 110, the electrical contact can be established when the shielding element 100 is coupled to the corresponding device, since the projection 130 is pressed against the corresponding device, so as to establish electrical contact, during the coupling process.

Furthermore, in this second embodiment of the shielding element 100, provision is made for the electrically conductive layer 104 not to extend as far as the electrically conductive, sleeve-shaped element 124, and not to be electrically contacted therewith.

The inner seal element 128 is arranged between the electrically conductive element 124 and the electrically conductive layer 104 in order to form a seal with respect to the outer side 122.

The inner seal element 128 is arranged in a groove formed in the main body 102, said groove preferably being provided adjacent to the electrically conductive element 124.

In this embodiment, the inner seal element 128 is in particular designed so as to extend correspondingly to the projection 130 which extends along at least part of the edge portion 108 of the main body 102.

In particular, the inner seal element 128 extends correspondingly to the projection 130 along the edge portion 108 of the main body 102 around the entire periphery, for example as an annular seal.

The inner seal element 128 is formed in particular from an elastomer material, for example from a plastics material, from rubber or the like.

FIG. 3 shows a schematic sectional view of the shielding element 100 according to a third embodiment according to the disclosure, which constitutes a modification of the second embodiment.

In this third embodiment of the shielding element 100, instead of the seal element 128 which is composed of the elastomer material and received in the groove, said seal element is formed as a liquid seal.

This seal element 128 formed as a liquid seal is applied to a surface of the main body 102 on the inner side 110.

In particular, the seal element 128 formed as a liquid seal is provided between the projection 130 and the coupling device 114.

Preferably, in this embodiment, too, provision is made for the seal element 128 formed as a liquid seal to extend correspondingly to the projection 130, which extends along at least part of the edge portion 108 of the main body 102.

In particular, the seal element 128 formed as a liquid seal extends correspondingly to the projection 130 along the edge portion 108 of the main body 102 around the entire periphery.

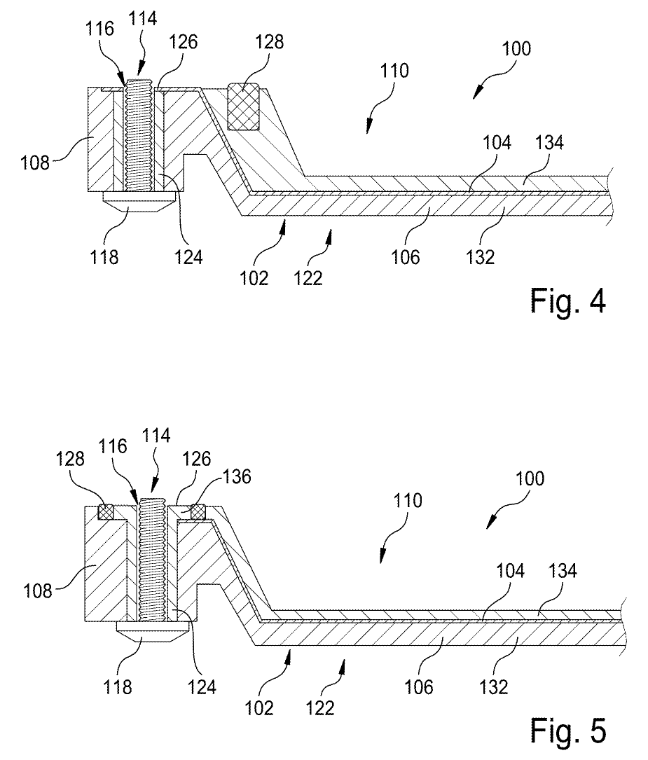

FIG. 4 shows a schematic sectional view of the shielding element 100 according to a fourth embodiment according to the disclosure.

Only differences between this fourth embodiment of the shielding element 100 and the above-described embodiments of the shielding element 100 will be discussed below. Equivalent designs will not be discussed again, and may in particular correspond to the previous embodiments of the shielding element 100.

In this fourth embodiment of the shielding element 100, the main body 102 is formed as a multi-ply main body 102.

This multi-ply main body 102 comprises an outer ply 132 and an inner ply 134.

The electrically conductive layer 104 is arranged between the outer ply 132 and the inner ply 134.

The electrically conductive layer 104 is preferably arranged between the outer ply 132 and the inner ply 134 so as to be exposed toward the inner side 110 in the region of the coupling device 114. The electrically conductive contact portion 126 is thus formed, in the region of the coupling device 114, by the electrically conductive layer 104.

In this way, in the case of this multi-ply design of the main body 102, the electrically conductive contact portion 126 can be formed in the region of the coupling device 114.

The outer ply 132 and the inner ply 134 of the multi-ply main body 102 are preferably formed from the same material. In particular, the outer ply 132 and/or the inner ply 134 are formed by way of an injection molding operation, a foam injection molding operation, an injection compression molding operation or a pressing operation, in which the electrically conductive layer 104 is arranged between the outer ply 132 and inner ply 134.

Alternatively, provision may also be made for the multi-ply main body 102 to be formed by way of a multi-component injection molding operation, foam injection molding operation, injection compression molding operation or pressing operation, in which the outer ply 132 is formed by a first component, in particular injection molding component, and the inner ply 134 is formed from a further component, in particular injection molding component.

The inner seal element 128 is arranged in a groove formed in the inner ply 134 of the main body 102, said groove preferably being provided to the inside of the electrically conductive contact portion 126.

The inner seal element 128 is designed to extend along at least part of the edge portion 108 of the main body 102, in particular along the edge portion 108 of the main body 102 around the entire periphery, for example as an annular seal.

The inner seal element 128 is formed in particular from an elastomer material, for example from a plastics material, from rubber or the like.

FIG. 5 illustrates a schematic sectional view of the shielding element 100 according to a fifth embodiment according to the disclosure, which constitutes a modification of the fourth embodiment.

In this fifth embodiment of the shielding element 100, the electrically conductive, sleeve-shaped element 124 in the passage 116 has a flange portion 136 which is arranged on the inner side 110 of the main body 102.

Said flange portion 136 forms the electrically conductive contact portion 126 with respect to the inner side 110 of the main body 102. During the coupling to the corresponding device, the shielding element 100 is electrically contactable with said device by means of the flange portion 136 of the electrically conductive element 124.

The electrically conductive layer 104 is contacted with the electrically conductive element 124 such that electrical contact is established with the electrically conductive layer 104 during the coupling to the corresponding device.

In the region of the coupling device 114, the outer ply 132 and the inner ply 134 of the main body 102 are designed such that the flange portion 136 of the electrically conductive element 124 is arranged flush with a surface of the main body 102.

Provision may also be made for the flange portion 136 of the electrically conductive element 124 to protrude relative to the surface of the main body 102.

The inner seal element 128 is received in a recess formed by the outer ply 132 and the inner ply 134 and is arranged adjacent to the flange portion 136 of the electrically conductive element 124.

The recess formed by the outer ply 132 and the inner ply 134 is designed in particular to receive both the flange portion 136 of the electrically conductive element 124 and the inner seal element 128.

The inner seal element 128 is preferably formed as an annular seal, for example as an O-ring, which surrounds the flange portion 136 of the electrically conductive element 124.

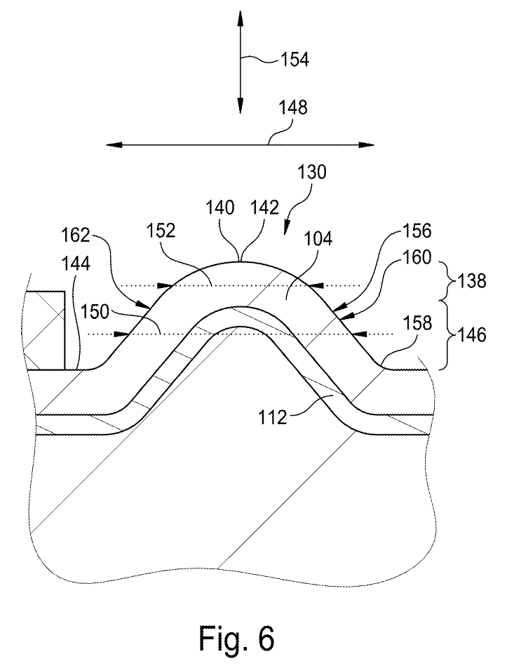

FIG. 6 shows the electrically conductive projection 130 from FIG. 3 in an enlarged illustration.

It may be advantageous if the electrically conductive projection 130 has an elevated projection zone 138.

The projection zone 138 may advantageously be electrically conductive in particular at a most highly elevated contact zone 140 of the projection. For example, the contact zone 140 may form a summit zone 142 of the projection 130.

The projection zone 138 may in particular be elevated in relation to a base portion 144 of the shielding element 100.

It may be advantageous if the electrically conductive projection 130 has a body zone 146 and the projection zone 138, wherein the projection 130 is more highly elevated in the projection zone 138 than in the body zone 146.

It may be advantageous if the projection 130 has a greater extent 150 in at least one projection extent direction 148 in the body zone 146 than in the more highly elevated projection zone 138. The greater extent is denoted in FIG. 6 by the reference sign 150, and the smaller extent is denoted by the reference sign 152.

The at least one projection extent direction 148 may advantageously extend transversely to a projection elevation direction 154 in which the projection 130 is elevated.

It may be advantageous if the projection 130 tapers from the body zone 146 via the projection zone 138 toward the contact zone 140.

For example, the projection 130 may have a flank 156.

The flank 156 may advantageously extend obliquely and/or be inclined relative to the projection elevation direction 154.

For example, as shown in FIG. 6, a gradient of the flank 156 may, at at least one point, be neither horizontal nor vertical. In the case of the projection 130 shown in FIG. 6, the gradient of the flank 156 is not vertical at any point, and is horizontal substantially only at the very top in the contact zone 140.

The terms horizontal and vertical may advantageously relate to the projection elevation direction 154, wherein vertical may mean parallel to the projection elevation direction 154 and horizontal may mean orthogonal to the projection elevation direction 154.

A gradient of the flank 156 may advantageously increase from the contact zone 140 toward the body zone 146, and/or decrease at the transition 158 from the body zone 146 into the base portion 144.

The electrically conductive layer 104 may advantageously entirely or partially cover or form the flank 156.

The electrically conductive layer 104 may advantageously extend on the flank 156 over the body zone 146 and the projection zone 138 up to the contact zone 140.

For example, the flank 156 may be a first flank 160, and the projection 130 may have a second flank 162.

It may be advantageous if the projection 130 has the greater extent 150 in the at least one projection extent direction 148 in the body zone 146 than in the more highly elevated projection zone 138, wherein the extent 150, 152 in the projection extent direction 148 in the body zone 146 and in the projection zone 138 is measurable in each case from the first flank 160 to the second flank 162.

The electrically conductive layer 104 may advantageously entirely or partially cover or form the first flank 160 and entirely or partially cover or form the second flank 162.

The electrically conductive layer 104 may advantageously extend on the first flank 160 over the body zone 146 and the projection zone 138 up to the contact zone 140, and extend on the second flank 162 from the contact zone 140 down through the projection zone 138 into the body zone 146 or through the body zone 146.

### List of reference signs

100 Shielding element

102 Main body

104 Electrically conductive layer

106 Wall portion

108 Edge portion

110 Inner side

112 Adhesion promoter

114 Coupling device

116 Passage

118 Fastening means

120 External seal element

122 Outer side

124 Sleeve-shaped element

126 Contact portion

128 Inner seal element

130 Electrically conductive projection

132 Outer ply

134 Inner ply

136 Flange portion

138 Projection zone

140 Contact zone

142 Summit zone

144 Base portion

146 Body zone

148 Projection extent direction

150 Greater extent

152 Smaller extent

154 Projection elevation direction

156 Flank

158 Transition from the body zone into the base portion

160 First flank

162 Second flank

1. A shielding element for electrically shielding an electronic component, said shielding element comprising:
a main body, which has a coupling device by which the main body is couplable to a corresponding device; and
at least one electrically conductive layer, which is provided at least in certain regions on and/or in the main body, wherein
the main body and the at least one electrically conductive layer are interconnected.

2. The shielding element according to claim 1, wherein the main body and the at least one electrically conductive layer are joined together by means of an injection molding operation, an injection compression molding operation and/or a pressing operation.

3. The shielding element according to claim 1, wherein the coupling device has at least one electrically conductive contact portion by means of which the coupling device can be electrically contacted with the corresponding device.

4. The shielding element according to claim 3, wherein the at least one electrically conductive contact portion is formed at least in part by the electrically conductive layer and/or is contacted with the at least one electrically conductive layer.

5. The shielding element according to claim 3, wherein
the coupling device has at least one passage provided in the main body, and
an electrically conductive element is provided in the passage and forms the contact portion and/or is contacted with the contact portion.

6. The shielding element according to claim 5, wherein the at least one electrically conductive contact portion is formed at least in part by an end face or a flange portion of the electrically conductive element.

7. The shielding element according to claim 5, wherein the electrically conductive element is an electrically conductive sleeve.

8. The shielding element according to claim 1, wherein at least one electrically conductive projection is provided on the main body by means of which, during the coupling to the corresponding device, the electrically conductive layer is electrically contactable with said device.

9. The shielding element according to claim 1, wherein the electrically conductive layer is formed at least in part from a metallic material, or from aluminum, copper, iron, nickel, and/or silver.

10. The shielding element according to claim 1, wherein the electrically conductive layer is formed at least in part as a foil, and the foil is a metal foil, wherein a thickness of the metal foil is 0.03 to 0.6 mm.

11. The shielding element according to claim 1, wherein the electrically conductive layer is formed at least in part from an electrically conductive organic material, or from carbon, or carbon fibers, and/or graphite.

12. The shielding element according to claim 1, wherein the electrically conductive layer is formed at least in part from a combination of an electrically conductive material and an electrically non-conductive material.

13. The shielding element according to claim 1, wherein the electrically conductive layer is formed at least in part from a woven fabric, a laid scrim, a weft-knitted fabric, a warp-knitted fabric, and/or a nonwoven, which is provided with an electrically conductive material.

14. The shielding element according to claim 1, wherein the electrically conductive layer is formed at least in part as a foil, a metal sheet, a perforated metal sheet, an expanded metal, or an expanded metal mesh.

15. The shielding element according to claim 1, wherein an adhesion promoter is provided at least in certain regions between the main body and the electrically conductive layer.

16. The shielding element according to claim 1, wherein the electrically conductive layer has, at least in certain regions, a layer thickness of at least approximately 0.005 mm and/or at most approximately 1 mm.

17. The shielding element according to claim 1, wherein, at least in certain regions, there is a ratio of approximately 1/1 to approximately 1/10000 between a layer thickness of the electrically conductive layer and a thickness of the main body.

18. The shielding element according to claim 1, wherein
the main body is formed as a multi-ply injection-molded part, and
the at least one electrically conductive layer is provided at least between two adjacent plies.

19. The shielding element according to claim 7, wherein
the electrically conductive projection has an elevated projection zone and a flank,
the flank extends obliquely and/or is inclined relative to the projection elevation direction,
the electrically conductive layer entirely or partially covers or forms the flank, and/or
the projection zone is electrically conductive at a most highly elevated contact zone of the projection.

20. The shielding element according to claim 1, wherein the shielding element is a lid element, a housing element, and/or a cover element.
